(19) United States
(12) Patent Application Publication
(10) Pub. No.: US 2012/0193518 A1
(43) Pub. Date: Aug. 2, 2012

(54) PHOTORECEPTOR CIRCUIT AND PHOTOCOUPLER

(75) Inventors: Masafumi SHIMIZU, Otsu (JP); Setsuya Oku, Ots (JP)

(73) Assignee: Renesas Electronics Corporation

(21) Appl. No.: 13/352,954

(22) Filed: Jan. 18, 2012

(30) Foreign Application Priority Data
Jan. 28, 2011 (JP) 2011-016758

(51) Int. Cl. H03F 3/08

(52) U.S. Cl. 250/214 A

(57) ABSTRACT

A photoreceptor circuit includes: a first amplifier circuit where a feedback resistor is coupled between an input and output of an inverting amplifier; a second amplifier circuit that has a configuration substantially identical to a configuration of the first amplifier circuit and supplies a bias current to the first amplifier circuit; a photodiode having an anode coupled to an input of the first amplifier circuit and a cathode coupled to an input of the second amplifier circuit; and a first resistor coupled between an output of the second amplifier circuit and the input of the first amplifier circuit.

### CROSS-REFERENCE TO RELATED APPLICATIONS

The disclosure of Japanese Patent Application No. 2011-16758 filed on Jan. 28, 2011 including the specification, drawings and abstract is incorporated herein by reference in its entirety.

### BACKGROUND

The present invention relates to a photoreceptor circuit and a photocoupler.

Examples of the circuit configuration of an amplifier for amplifying into a voltage a photocurrent generated by a photodiode in accordance with light input in a photocoupler or the like including a bipolar transistor include technologies such as Japanese Unexamined Patent Publication No. 2004-328061.

FIG. 7 shows a block configuration of a photoreceptor circuit 300 of a related art which is modified that of Japanese Unexamined Patent Publication No. 2004-328061. As shown in FIG. 7, the photoreceptor circuit 300 includes a current/voltage conversion circuit (I/V conversion circuit) 301, a bias setting circuit 304, a voltage amplifier 302, a base current correction reference amplifier 303, an output transistor Q301, a photodiode PD301, resistors R301 to R307, a capacitor C301, and an output terminal OUT. The photoreceptor circuit 300 is an open collector output circuit, and an external pull-up resistor (not shown) is coupled between the output terminal OUT and a power supply terminal.

The photodiode PD301 has an anode coupled to a node N301 and a cathode coupled to a node N305. The output transistor Q301 has a collector coupled to the output terminal OUT, an emitter coupled to a ground terminal GND, and a base coupled to a node N309. The capacitor C301 is coupled between the node N301 and a node N306.

The resistor R301 is coupled between the node N301 and a node N302. The resistor R302 is coupled between the node N302 and a node N303. The resistor R303 is coupled between the node N303 and a node N304. The resistor R304 is coupled between the node N304 and the node N309. The resistor R305 is coupled between the node N305 and the node N306. The resistor R306 is coupled between a node N307 and a node N308. The resistor R307 is coupled between the node N301 and the node N307.

The I/V conversion circuit 301 has an input coupled to the node N301 and an output coupled to the node N302. The voltage amplifier 302 has an input coupled to the node N303 and an output coupled to the node N304. The base current correction reference amplifier 303 has an input coupled to the node N308 and an output coupled to the node N307. The bias setting signal 304 has an input coupled to the node N305 and an output coupled to the node N306.

FIG. 8 shows detailed configurations of the related art of circuits adjacent to the photodiode PD301 and coupling relationships between the circuits. As shown in FIG. 8, the I/V conversion circuit 301 includes resistors R401 and R402 and NPN bipolar transistors (hereafter simply referred to as transistors) Q401 and Q402. The resistor R401 is coupled between a power supply terminal Vcc and a node N401. The transistor Q401 has a collector coupled to the node N401, an emitter coupled to the ground terminal GND, and a base coupled to the node N301. The transistor Q402 has a collector coupled to the power supply terminal Vcc, an emitter coupled to the node N302, and a base coupled to the node N401. The resistor R402 is coupled between the node N302 and the ground terminal GND.

The bias setting circuit 304 includes resistors R403 and R404 and transistors Q403 and Q404. The resistor R403 is coupled between the power supply terminal Vcc and a node N402. The transistor Q403 has a collector coupled to the node N402, an emitter coupled to the ground terminal GND, and a base coupled to the node N305. The transistor Q404 has a collector coupled to the power supply terminal Vcc, an emitter coupled to the node N306, and a base coupled to the node N402. The resistor R404 is coupled between the node N306 and the ground terminal GND.

The base current correction reference amplifier 303 includes resistors R405 and R406 and transistors Q405 and Q406. The resistor R405 is coupled between the power supply terminal Vcc and a node N403. The transistor Q405 has a collector coupled to the node N403, an emitter coupled to the ground terminal GND, and a base coupled to the node N308. The transistor Q406 has a collector coupled to the power supply terminal Vcc, an emitter coupled to the node N307, and a base coupled to the node N403. The resistor R406 is coupled between the node N307 and the ground terminal GND.

The configuration of the voltage amplifier 302 is basically the same as those of the I/V conversion circuit 301, the bias setting circuit 304, and the base current correction reference amplifier 303 and will not be described in detail.

When light enters the photodiode PD301, a photocurrent ipd according to the intensity of the light flows from the cathode to the anode. The I/V conversion circuit 301 then receives the photocurrent ipd. Here the resistor R301 serves as a feedback resistor. The I/V conversion circuit 301 thus generates a voltage Vo301, which is lower than that at ipd=0 by ipd×R301, as an output voltage Vo301. The voltage amplifier 302 then receives the voltage Vo301.

The voltage amplifier 302 generates a voltage Vo302, which is lower than that at ipd=0 by Vo301×R303/R302 owing to the relationship between the feedback resistors R302 and R303, as an output. When this voltage reaches or exceeds a threshold voltage Vth of the output transistor Q301, the output transistor Q301 is turned on and an output voltage VOUT to be outputted from the output terminal OUT becomes a low level.

As shown in FIG. 8, the input of the I/V conversion circuit 301 is the base of the transistor Q401 having the grounded emitter, thereby requiring a base current. When no light enters the photodiode PD301, this base current is supplied via the feedback resistor R301. Accordingly, the output voltage Vo301 of the I/V conversion circuit 301 is obtained by the following formula:

Vo301=IBQ401×R301 Formula 1

where IBQ401 represents the base current of the transistor Q401.

In other words, when no light enters the photodiode PD301, voltage Vo301 is always a voltage increased by this value.

In contrast, when light enters the photodiode PD301, the base current of the transistor Q401 is the sum of a current supplied via the feedback resistor R301 and the photocurrent ipd generated by the photodiode PD301. Because of a part of the photocurrent ipd consumed as the base current of the transistor Q401, apparent sensitivity of the output of the I/V conversion circuit 301 is lowered. Specifically, since the photocurrent ipd is as small as the order of “μA,” the output voltage Vo301 does not decrease when intense light does not enter the photodiode PD301. As a result, the output voltage VOUT does not become a low level.

To address this problem, the photoreceptor circuit 300 uses the base current correction reference amplifier 303, whose output is coupled to the input of the I/V conversion circuit 301 via the resistor R307. Here it is assumed that the I/V conversion circuit 301 and the base current correction reference amplifier 303 have the same circuit configuration and that each configuration has the same constants (such as resistances and the dimensions of the transistors). Further, the resistances of the resistor R307 and the feedback resistor R301 are set to the same value. These equalize the output voltage Vo301 of the I/V conversion circuit 301 and an output voltage Vo303 of the base current correction reference amplifier 303. Accordingly, currents IR301 and IR307 passing through the resistors R301 and R307, respectively, are obtained by the following formula:

$$IR 301 = \frac{( Vo 301 - Vin 301 )}{R 301} \\ IR 307 = \frac{( Vo 303 - Vin 301 )}{R 307} \qquad Formula 2$$

where Vin301 represents the input voltage of the I/V conversion circuit 301.

Substitution of the above-mentioned Vo301=Vo303 and R301=R307 into the above formula results in IR301=IR307.

As seen, the current supply to the I/V conversion circuit 301 by the base current correction reference amplifier 303 can prevent the consumption of the photocurrent ipd as the base current of the transistor Q401 of the I/V conversion circuit 301 from reducing apparent sensitivity.

Further, changing the resistance of the resistor R307 or any constant of the base current correction reference amplifier 303 can change the amount of the correction current to be supplied to the I/V conversion circuit 301. This can adjust an input light level IFHL at which the output of the photocoupler changes from a high level to a low level.

The bias setting circuit 304 has the following functions. A variation in the power supply voltage Vcc causes a variation in the potential of each amplifier (301 to 304), and the photodiode PD301 has a parasitic capacitance Cpd. When a variation in power supply voltage causes a potential difference between the anode and cathode of the photodiode PD301, the parasitic capacitance Cpd is charged or discharged. When the I/V conversion circuit 301 receives the resulting current, it operates as it does when receiving the photocurrent ipd. That is, the I/V conversion circuit 301 is turned on or off, whether or not it has received the photocurrent ipd. Thus the photoreceptor circuit 300 malfunctions.

For this reason, the bias setting circuit 304 having the same circuit configuration and constants as the I/V conversion circuit 301 is coupled to the cathode of the photodiode PD301. This prevents the photoreceptor circuit 300 from malfunctioning owing to a variation in power supply voltage. Further, to achieve both noise immunity and high-speed responsiveness, the capacitor C301 is coupled between the output of the bias setting circuit 304 and the input of the I/V conversion circuit 301.

### SUMMARY

If the element for receiving the photocurrent ipd is the base of the bipolar transistor Q401, the photocurrent ipd is consumed as a base current. For this reason, light having any intensity is converted into apparently smaller photocurrent ipd by the photodiode PD301. This increases the threshold Vth, which could prevent turn-on of the photoreceptor circuit 300 in the worst condition.

For this reason, as shown in FIG. 8 of the related art, a current for offsetting the base current from the base current correction reference amplifier 303 is applied to the node between the anode of the photodiode PD301 and the base of the bipolar transistor Q401 for receiving the photocurrent ipd.

However, the requirement to reduce the chip cost, including that of the photocoupler, has been increased in recent years, requiring reductions in circuit size. Accordingly, the number of circuit components must be reduced as much as possible. Unfortunately, elimination of the base current correction reference amplifier 303 would prevent turn-on of the photoreceptor circuit 300 as described above.

A photoreceptor circuit according to an aspect of the present invention includes: a first amplifier circuit where a feedback resistance is coupled between an input and output of an inverting amplifier; a second amplifier circuit that has a configuration substantially identical to a configuration of the first amplifier circuit and supplies a bias current to the first amplifier circuit; a photodiode having an anode coupled to an input of the first amplifier circuit and a cathode coupled to an input of the second amplifier circuit; and a first resistor coupled between an output of the second amplifier circuit and the input of the first amplifier circuit.

In the aspect of the present invention, the input of the first amplifier circuit and the output of the second amplifier circuit are coupled by the first resistor. Thus, when no light enters the photodiode, the second amplifier circuit can supply a correction current to the first amplifier circuit through the first resistor, eliminating the need to prepare a special correction current supply circuit.

According to the aspect of the present invention, the circuit size can be reduced.

### BRIEF DESCRIPTION OF THE DRAWINGS

FIG. 1 shows the configuration of a photoreceptor circuit according to an embodiment of the present invention;

FIG. 2 shows the configuration of a photoreceptor circuit according to this embodiment;

FIG. 3 shows input/output characteristics of a photoreceptor circuit according to the related art;

FIG. 4 shows input/output characteristics of the photoreceptor circuit according to this embodiment;

FIG. 5 is a graph showing common mode rejection (CMR) characteristics according to the related art;

FIG. 6 is a graph showing CMR characteristics of the photoreceptor circuit according to this embodiment;

FIG. 7 shows the configuration of a photoreceptor circuit according to the related art;

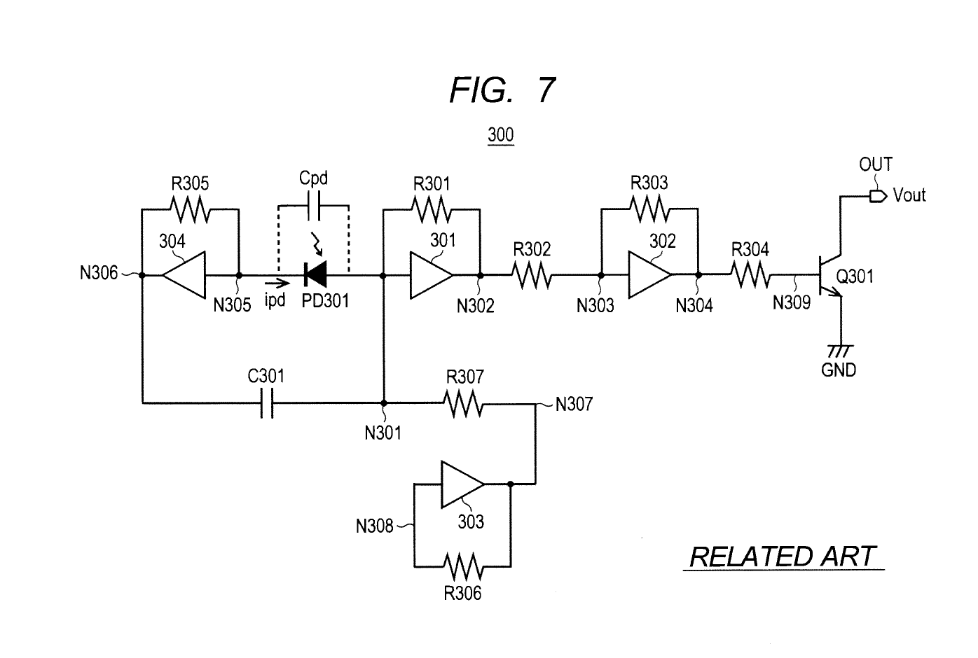

FIG. 8 shows the configuration of the photoreceptor circuit according to the related art; and

FIG. 9 shows a configuration of a photocoupler according to this embodiment.

### DESCRIPTION OF THE PREFERRED EMBODIMENTS

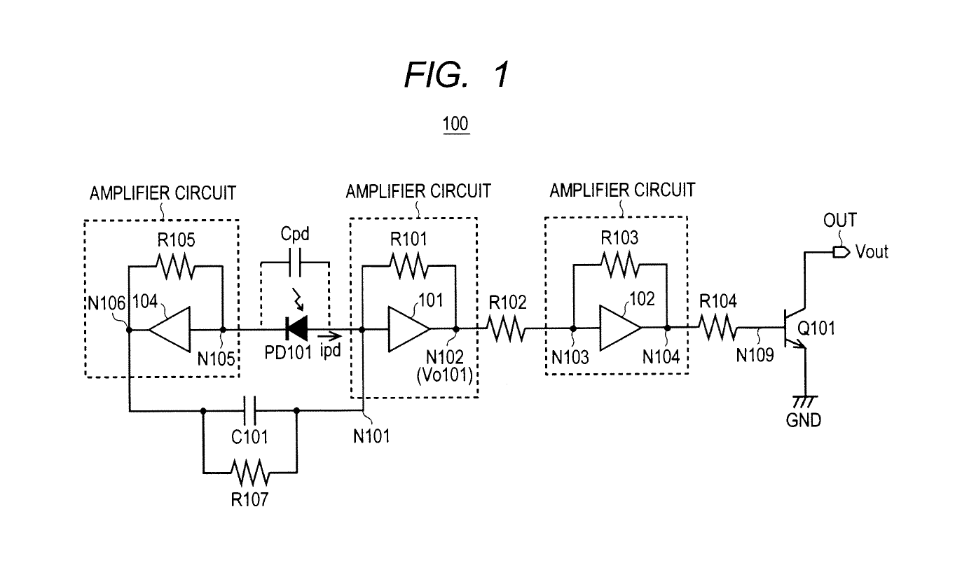

Now, a specific embodiment of the present invention will be described in detail with reference to the accompanying drawings. This embodiment is a photoreceptor circuit suitable for a photocoupler. FIG. 1 shows a block configuration of a photoreceptor circuit 100 according to this embodiment. While the photoreceptor circuit 100 also includes input circuit blocks for converting an input electrical signal into an optical signal and outputting the optical signal to a photodiode PD101 (to be discussed later) as a matter of course, the input circuit blocks are omitted to simplify the drawing.

As shown in FIG. 1, the photoreceptor circuit 100 includes a current/voltage conversion circuit (I/V conversion circuit) 101, a bias setting circuit 104, a voltage amplifier 102, an output transistor Q101, a photodiode PD101, resistors R101 to R105 and R107, a capacitor C101, and an output terminal OUT. The photoreceptor circuit 100 is an open collector output circuit, and an external pull-up resistor (not shown) is coupled between the output terminal OUT and a power supply terminal.

The current/voltage conversion circuit 101 has an anode coupled to a node N101 and a cathode coupled to a node N105. The output transistor Q101 has a collector coupled to the output terminal OUT, an emitter coupled to a ground terminal GND, and a base coupled to node N109. The capacitor C101 is coupled between the node N101 and a node N106. As with the capacitor C301 according to the related art, the capacitor 0101 has the function of providing both noise immunity and high-speed responsiveness for the photoreceptor circuit 100.

The resistor R101 is coupled between the node N101 and a node N102. The resistor R102 is coupled between the node N102 and a node N103. The resistor R103 is coupled between the node N103 and a node N104. The resistor R104 is coupled between the node N104 and the node N109. The resistor R105 is coupled between the node N105 and the node N106. The resistor R107 is coupled between the node N101 and the node N106. It is assumed that the resistors R101, R103, and R105 are the same constant.

The I/V conversion circuit 101 has an input coupled to the node N101 and an output coupled to the node N102. The voltage amplifier 102 has an input coupled to the node N103 and an output coupled to the node N104. The bias setting circuit 104 has an input coupled to the node N105 and an output coupled to the node N106.

The resistors R101, R103, and R105 are the feedback resistors of the I/V conversion circuit 101, the voltage amplifier 102, and the bias setting circuit 104, respectively. The I/V conversion circuit 101, the voltage amplifier 102, and the bias setting circuit 104 are inverting amplifiers having basically the same configuration. Accordingly, the resistor R101 and the I/V conversion circuit 101, the resistor R103 and the voltage amplifier 102, and the resistor R105 and the bias setting circuit 104 each form an amplifier circuit for inverting and amplifying a received voltage.

The I/V conversion circuit 101, the bias setting circuit 104, the I/V conversion circuit 101, the resistors R101, R105, and R107, and the capacitor C101 form a photoreceptor circuit.

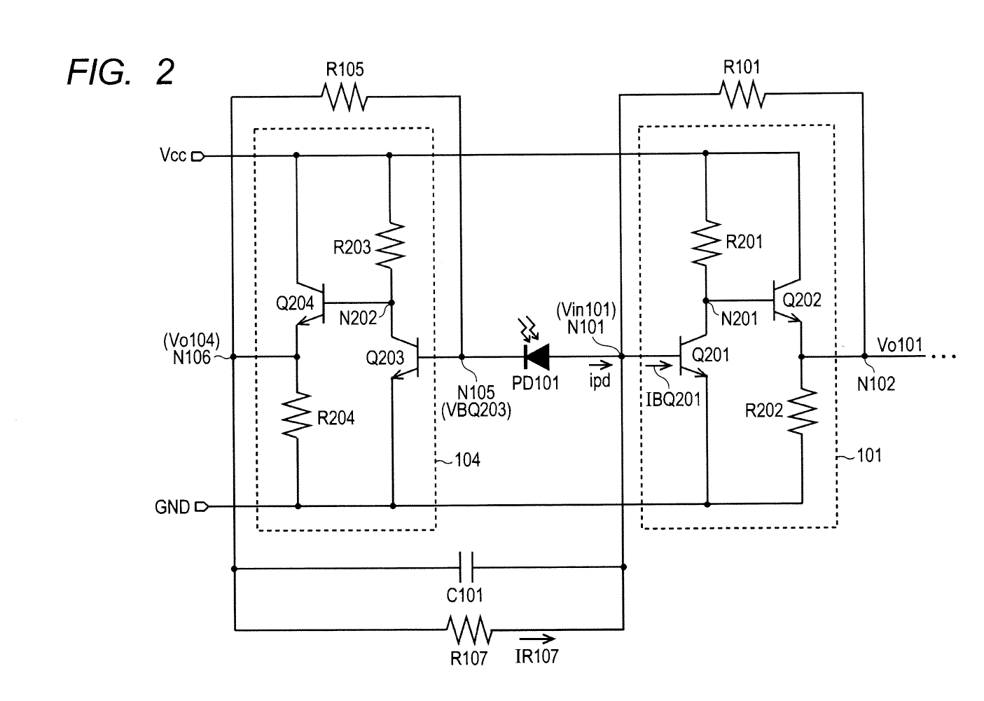

FIG. 2 shows detailed configurations of circuits adjacent to the photodiode PD101 and coupling relationships between the circuits. As shown in FIG. 2, the I/V conversion circuit 101 includes resistors R201 and R202 and NPN bipolar transistors (hereafter simply referred to as transistors) Q201 and Q202. The resistor R201 is coupled between the power supply terminal Vcc and a node N201. The transistor Q201 has a collector coupled to the node N201, an emitter coupled to the ground terminal GND, and a base coupled to the node N101. The transistor Q202 has a collector coupled to the power supply terminal Vcc, an emitter coupled to the node N102, and a base coupled to the node N201. The resistor R202 is coupled between the node N102 and the ground terminal GND.

The bias setting circuit 104 includes resistors R203 and R204 and transistors Q203 and Q204. The resistor R203 is coupled between the power supply terminal Vcc and a node N202. The transistor Q203 has a collector coupled to the node N202, an emitter coupled to the ground terminal GND, and a base coupled to the node N105. The transistor Q204 has a collector coupled to the power supply terminal Vcc, an emitter coupled to the node N106, and a base coupled to the node N202. The resistor R204 is coupled between the node N106 and the ground terminal GND.

The capacitor C101 and the resistor R107 are coupled in parallel between the nodes N101 and N106.

The configuration of the voltage amplifier 102 is basically the same as those of the I/V conversion circuit 101 and the bias setting circuit 104 and will not be described in detail.

The photocurrent ipd does not flow unless light enters the photodiode PD101.

Assuming that the circuit blocks (the I/V conversion circuit 101, the voltage amplifier 102, and the bias setting circuit 104) have the same circuit configuration and that the feedback resistors, the resistors R101, R105, and R107, have the same resistance, consider the operation of the photoreceptor circuit 100.

The bias setting circuit 104 supplies a current to the input of the I/V conversion circuit 101, the base of the transistor Q201, via the resistor R107. Accordingly, no current passes through the resistor R101, and the output voltage of the I/V conversion circuit 101 (the voltage of the node N102) becomes the same as the input voltage (the voltage of the node N101), that is, becomes the same as the base voltage of the transistor Q201.

The voltage amplifier 102 then receives the output voltage of the I/V conversion circuit 101 but does not amplify it, since no current has passed through the resistor R101. Accordingly, the output voltage of the voltage amplifier 102 (the voltage of the node N104) also becomes the same as the base voltage of the transistor Q201. Thus the base voltage of the output transistor Q101, which is based on the output voltage of the voltage amplifier 102 (the voltage of the node N104), comes close to a threshold voltage of the output transistor Q101. This poses a risk that the output transistor Q101 could be turned on even when no light enters the photodiode PD101.

To eliminate such a risk, it is necessary to provide an offset. For this reason, in this embodiment, the resistance of the resistor R107 is set not to the same value as those of the resistors R101 and R105 but to a value greater than those so that the output transistor Q101 is not turned on unless light having predetermined intensity enters. This makes the current supplied to the I/V conversion circuit 101 smaller than the base current of the transistor Q201. Thus the output voltage of the voltage amplifier 102 is set to a value lower than the threshold voltage, at which the output transistor Q101 is turned on. This is expressed by the following formula:

IBQ 201>IR107 Formula 3

where IR107 represents the current passing through the resistor R107 and IBQ201 represents the base current of the transistor Q201.

An output voltage Vo101 of the I/V conversion circuit 101 is obtained by the following formula:

Vo101=VBQ 201+(IBQ 201−IR107)×R101 Formula 4

When light enters the photodiode PD101, the photocurrent ipd according to the intensity of the light flows from the cathode to the anode. The I/V conversion circuit 101 then receives the photocurrent ipd. If the photocurrent ipd is large enough, it is represented by the following formula:

ipd>IBQ 201−IR107 Formula 5

Here the resistor R101 acts as a feedback resistor, and the I/V conversion circuit 101 generates the voltage Vo101 that is lower than that at ipd=0 by the following value, as an output:

(ipd−(IBQ 201−IR107))×R101 Formula 6

The voltage amplifier 102 receives the voltage Vo101 thus generated. It then outputs a voltage Vo102 which is higher than that at ipd=0 by Vo101×R103/R102 owing to the relationship between the resistors R102 and R103. When the voltage Vo102 reaches or exceeds a threshold voltage Vth of the output transistor Q101, the output transistor Q101 is turned on and the level of the output terminal OUT becomes low level.

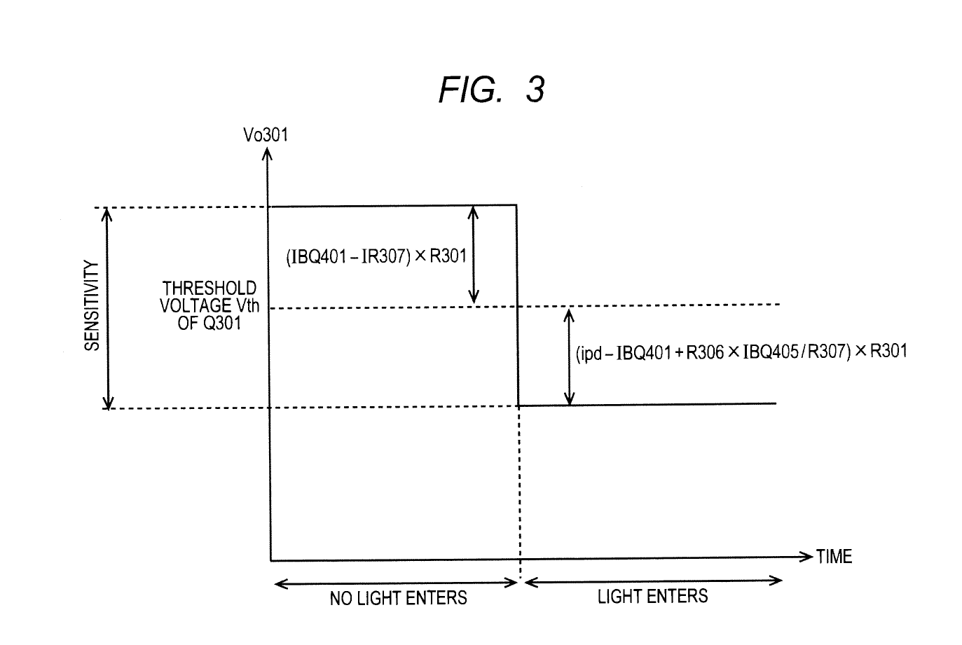

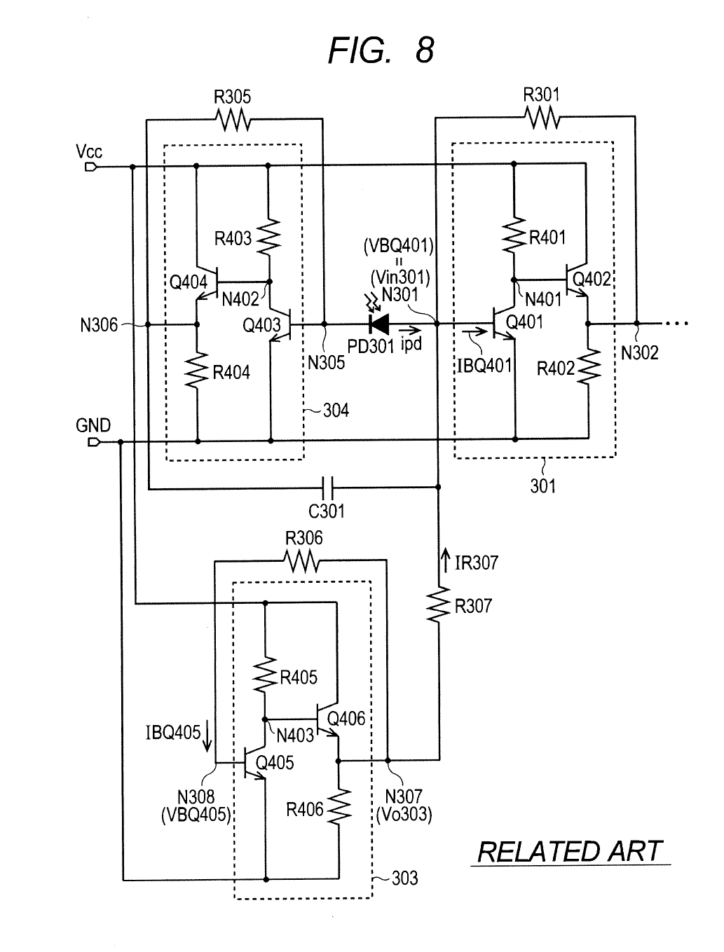

FIG. 3 shows the output voltage Vo301 of the I/V conversion circuit 301 according to the related art of FIG. 8 in a case where light enters and in a case where no light enters. As shown in FIG. 3, Vth represents the output voltage of the I/V conversion circuit 301 required to change the output of the photoreceptor circuit from a low level to a high level. That is, when the output voltage of the I/V conversion circuit 301 is equal to the threshold voltage Vth of the output transistor Q301 or higher, the output voltage Vout of the photocoupler 300 becomes a high level; when below Vth, it becomes a low level.

First, note the I/V conversion circuit 301 and the base current correction circuit 303 in a case where no light enters. Here it is assumed that the I/V conversion circuit 301 and the base current correction circuit 303 have the same circuit configuration and that the feedback resistors, the resistors R301 and R306, have the same resistance. An emitter voltage Vo303 of the transistor Q406, which is the output of the base current correction circuit 303, is obtained by the following formula:

Vo303=VBQ 405+IBQ 405×R306 Formula 7

where VBQ405 represents the base voltage of the transistor Q405, and IBQ405 represents the base current thereof.

A current IR307 passing through the resistor R307 is obtained from the voltages Vo303 and Vin301 of both terminals of the resistor R307 as follows:

$$\begin{matrix}IR 307 = \frac{\begin{matrix}( VBQ 405 + IBQ 405 \times R 306 ) - \\ VBQ 401\end{matrix}}{R 307} \\ = \frac{( IBQ 405 \times R 306 )}{R 307}\end{matrix} \qquad Formula 8$$

where VBQ405 represents the base voltage of the transistor Q405, which is the input of the base current correction reference amplifier 303, and IBQ405 represents the base current thereof.

Assuming that R307>R306=R301, IR307 is expressed as follows:

IR 307<IBQ 405=IBQ 401 Equation 9

where IBQ401 represents the base current of the transistor Q401.

Vo301 becomes higher than Vth by the following value, and the output of the photoreceptor circuit 300 becomes a high level:

(IBQ 401−IR 307)×R301 Formula 10

While the behavior of the IR307 in a case where light enters the photodiode PD301 is approximately the same as that in a case where no light enters it, consideration is given to the supply of ipd to the input of the I/V conversion circuit 301 by the photodiode PD301. Thus Vo301 becomes lower than Vth by the following value, and the output of the photoreceptor circuit 300 becomes a low level:

(ipd−(IBQ 401−IR 307))×R301 Formula 11

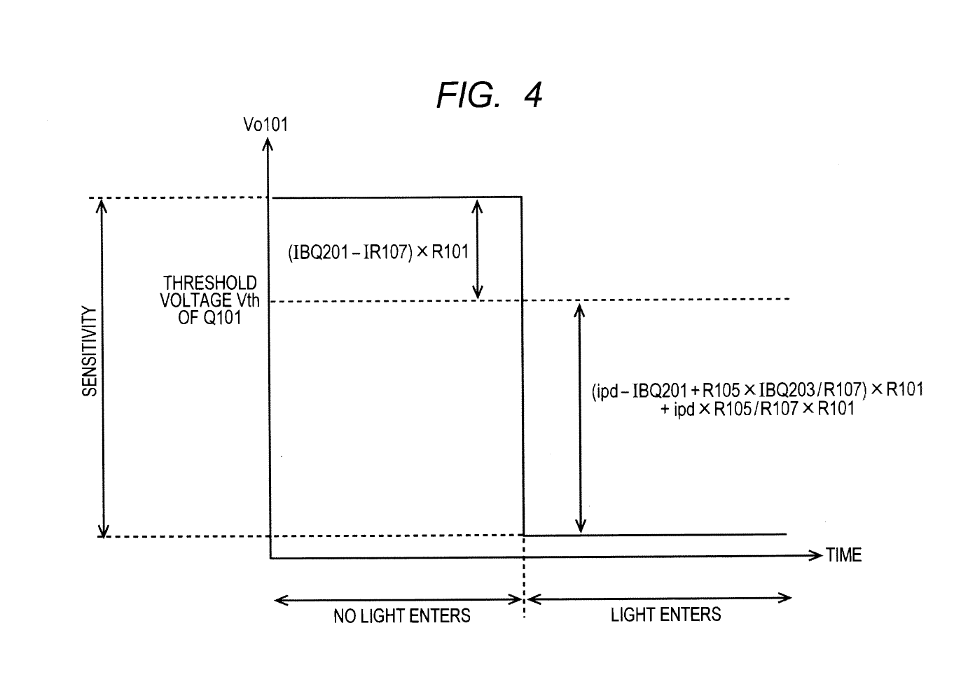

In contrast, an advantage of this embodiment will be described below. FIG. 4 shows the output voltage of the I/V conversion circuit 101 of FIG. 1 in a case where light enters and in a case where no light enters. As shown in FIG. 4, Vth represents the output voltage of the I/V conversion circuit 101 required to change the output of the photoreceptor circuit 100 from a low level to a high level. That is, when the output voltage of the I/V conversion circuit 101 is equal to the threshold voltage Vth of the output transistor Q101 or higher, the output voltage Vout of the photoreceptor circuit 100 becomes a high level; when below Vth, it becomes a low level.

Assume that R107>R105=R101. When no light enters the photodiode PD101, Vo101 becomes higher than Vth by the following value, and the output of the photoreceptor circuit 100 becomes a high level, as in the related-art circuit:

(IBQ 201−IR107)×R101 Formula 12

In contrast, when light enters the photodiode PD101, ipd passes through the resistor R105. Accordingly, an output voltage Vo104 of the bias setting circuit 104 is obtained by the following formula:

Vo104=VBQ 203+(IBQ 203+ipd)×R105 Formula 13

where VBQ203 represents the base voltage of the transistor Q203, and IBQ203 represents the base current thereof.

The current IR107 passing through the resistor R107 is obtained as the following value from the voltage Vo104 and the voltage Vin101 (the input voltage of the I/V conversion circuit 101) of both terminals of the resistor R107:

$$\begin{matrix}IR 107 = \frac{\begin{matrix}( VBQ 203 + ( IBQ 203 + ipd ) \times R 105 ) - \\ VBQ 201\end{matrix}}{R 107} \\ = \frac{( ( IBQ 203 + ipd ) \times R 105 )}{R 107}\end{matrix} \qquad Formula 14$$

The voltage Vo101 becomes lower than Vth by the following value, and the output of the photoreceptor circuit 100 becomes a low level:

(ipd−(IBQ 201−IR107))×R101 Formula 15

A comparison between the correction current IR307 according to the related art and the correction current IR107 according to this embodiment indicates that the current IR107 is higher than the current IR307 when light enters by the following value:

$$\frac{ipd \times R 105}{R 107} \qquad Formula 16$$

Similarly, a comparison between the output Vo101 of the I/V conversion circuit 101 and the output Vo301 of the I/V conversion circuit 301 indicates that Vo101 can be made lower than Vth by the following value:

$$\frac{ipd \times R 105}{R 107} \times R 101 \qquad Formula 17$$

As seen, even if light enters in the same way, the output of the I/V conversion circuit 101 according to this embodiment varies to a greater extent than in the related art. This means that this embodiment has higher apparent sensitivity. More specifically, it is understood that the following difference exists between Vo301 according to the related art and Vo101 according to this embodiment:

$$Vo 301 = ( ipd - IBQ 401 + \frac{R 306 \times IBQ 405}{R 307} ) \\ Vo 101 = ( ipd - IBQ 201 + \frac{R 105 \times IBQ 203}{R 107} ) \times R 101 + \frac{ipd \times R 105}{R 107} \times R 101 \qquad Formula 18$$

While R107 and R307 are adjusted in the above description in order to provide an offset voltage, it is understood from the above formula that the currents IR107 and IR307 passing through R107 and R307 may be made smaller than IBQ201 and IBQ401, respectively. Specifically, in the related art, any constant of the circuit forming the base current correction reference amplifier 303 may be adjusted; in this embodiment, any constant of the circuit forming the bias setting circuit 104 may be adjusted.

For example, the resistance of the resistor R203 of the bias setting circuit 104 is made larger than that of the resistor R201 of the I/V conversion circuit 101. Thus, even when the resistance of the resistor R107 coupled between the output of the bias setting circuit 104 and the input of the I/V conversion circuit 101 is set to the same value as those of the feedback resistors, the resistors R101 and R105, the correction base current received by the I/V conversion circuit 101 from the bias setting circuit 104 can be set to a value smaller than the base current of the input transistor of the I/V conversion circuit 101.

As seen, in this embodiment, it is possible to prevent a malfunction of the photocoupler while reducing the size of the circuit corresponding to the base current correction reference amplifier 303 required by the related art.

Meanwhile, characteristics specific to a photocoupler depending on the level difference between the threshold voltage and the signal voltage include common mode rejection (CMR). Improvements in the characteristics of photocouplers, as well as improvements in the CRM characteristics have been required in recent years. Among the characteristics of photocouplers required to be improved is speed-up depending on the feedback resistance. However, although increasing the difference between the threshold voltage and the signal voltage to improve the CRM increases an input light level IFHL, reducing the feedback resistance for speed-up would disadvantageously further increase IFHL.

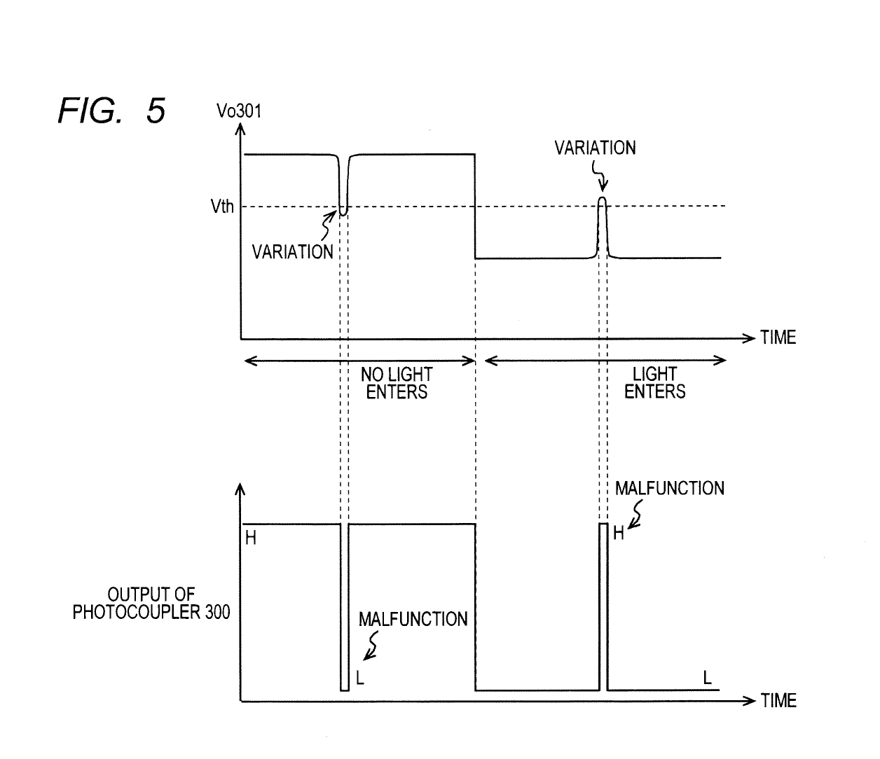

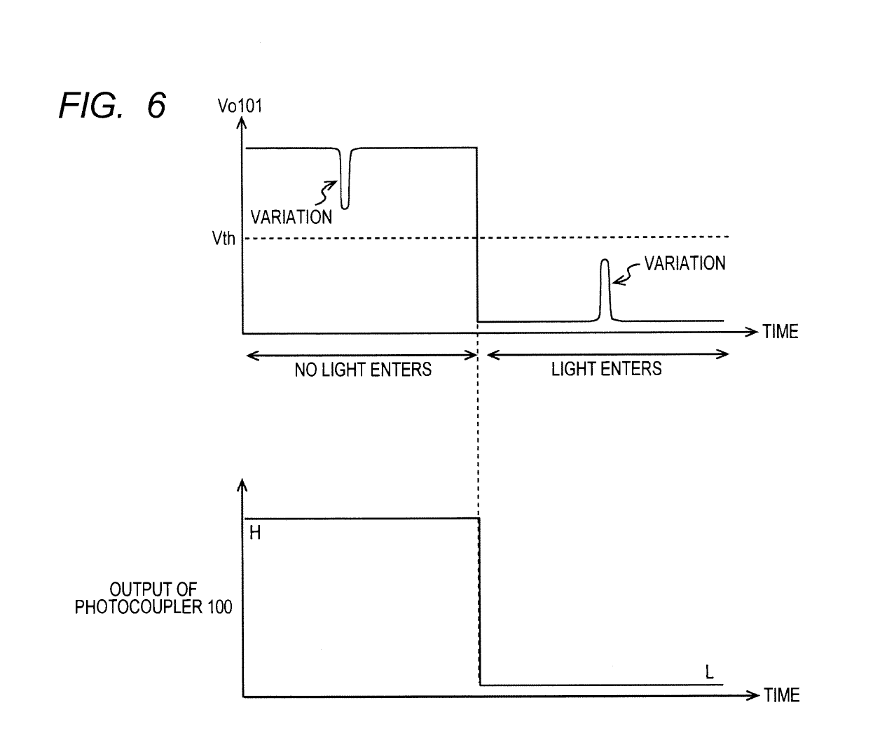

Common mode rejection (CMR) will be described with reference to FIGS. 5 and 6. FIG. 5 shows the output voltage waveform of the I/V conversion circuit 301 and the output wavelength of the photoreceptor circuit 300 according to the related art. FIG. 6 shows the output voltage wavelength of the I/V conversion circuit 101 and the output wavelength of the photoreceptor circuit 100 according to this embodiment.

As shown in FIG. 5, when noise enters the I/V conversion circuit 301 for some reason in the related art, the output of the I/V conversion circuit 301 varies. When the variation exceeds Vth, the output of the photoreceptor circuit 300 malfunctions.

In this embodiment, as shown in FIG. 6, the I/V conversion circuit 101 has a wide output dynamic range. Accordingly, Vth can be easily set in such a manner that variations in the output of the I/V conversion circuit 101 do not exceed Vth. Such a setting can prevent the output of the photoreceptor circuit 100 from malfunctioning, thereby improving CMR.

The above description will be described quantitatively. The output voltages Vo301 and Vo101 of the I/V conversion circuits according to this embodiment and the related art are simplified to facilitate the description.

In the related art, assuming that IBQ401=IBQ405 and R306 ≈R307, Vo301=ipd×R301. In this embodiment, assuming that IBQ201=IBQ203 and R105≈R107, Vo101=2×ipd×R101.

Assuming that the feedback resistance is the same in both the related art and this embodiment, when light with the same intensity enters, the I/V conversion circuit according to this embodiment receives twice the photocurrent ipd in the related art. Assuming that the output of the I/V conversion circuit is set to the same value in both the related art and this embodiment, the resistance of the feedback resistor, the resistor R101, is only required to be half that of the resistor R301 according to the related art. Thus the circuit size can be reduced.

Further, in this embodiment, the response speed of the I/V conversion circuit is determined by a CR time constant determined by the parasitic capacitance of the photodiode and the feedback resistance. As seen, the fact that the resistance of the feedback resistor can be halved advantageously increases the response speed of the I/V conversion circuit. This can speed up the circuit operation while improving CMR, without affecting the input light level (IFHL).

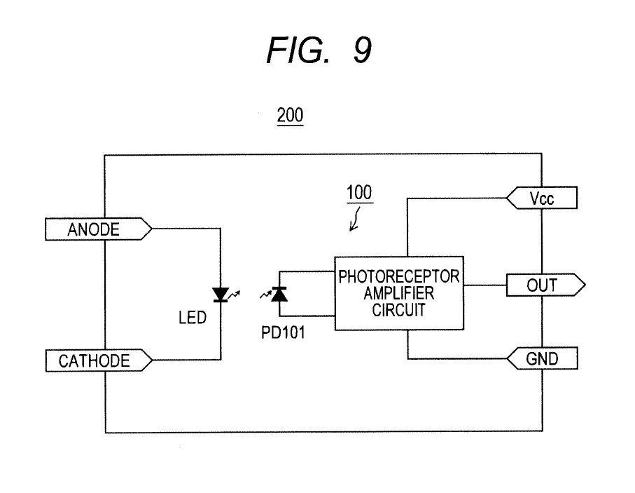

FIG. 9 shows a configuration of a photocoupler 200 using the photoreceptor circuit 100 shown in FIG. 1. An anode terminal, a cathode terminal, a LED coupled between the anode and cathode terminals, a power supply terminal Vcc, a ground terminal GND, an output terminal OUT, an photodiode PD101 and a photoreceptor circuit are shown in FIG. 9. The power supply terminal Vcc, the ground terminal GND, the output terminal OUT, the photodiode PD101 and the photoreceptor circuit are the same as that of the photoreceptor circuit 100. The remaining circuits in the photoreceptor circuit 100 such as I/V conversion circuit 101, the bias setting circuit 104, the voltage amplifier 102, the output transistor Q101, resistors R101 to R105 and R107, and the capacitor C101 are not drawn in FIG. 9 but included in a boxed element named photoreceptor circuit. When an input voltage is supplied between the anode and cathode terminals, a light is emitted from the LED and is received by the photodiode PD101 and amplified into a voltage to generate the output voltage Vout at the output terminal OUT.

The present invention is not limited to the above-mentioned embodiment, and changes can be made to the embodiment as appropriate without departing from the spirit and scope of the invention.

What is claimed is:

1. A photoreceptor circuit comprising:
a first amplifier circuit where a feedback resistor is coupled between an input and an output of an inverting amplifier;
a second amplifier circuit that has a configuration substantially identical to a configuration of the first amplifier circuit and supplies a bias current to the first amplifier circuit;
a photodiode having an anode coupled to an input of the first amplifier circuit and a cathode coupled to an input of the second amplifier circuit; and
a first resistor coupled between an output of the second amplifier circuit and the input of the first amplifier circuit.

2. The photoreceptor circuit according to claim 1, further comprising:
a capacitor coupled between the output of the second amplifier circuit and the input of the first amplifier circuit.

3. The photoreceptor circuit according to claim 1,
wherein respective input and output transistors of the first and second amplifier circuits each comprise a bipolar transistor, and the bias current supplied to the first amplifier circuit by the second amplifier circuit is smaller than a base current of the input transistor of the first amplifier circuit.

4. The photoreceptor circuit according to claim 3,
wherein the first resistor has a resistance higher than respective resistances of the feedback resistor of the first amplifier and a feedback resistor of the second amplifier circuit.

5. The photoreceptor circuit according to claim 3,
wherein the first and second amplifier circuits each include:
a first transistor serving as the input transistor;
a second transistor serving as the output transistor; and
second and third resistors,
wherein the second resistor has a first terminal coupled to a first power supply terminal and a second terminal coupled to a first node, the first transistor has a first terminal coupled to the first node, a second terminal coupled to a second power supply terminal, and a control terminal coupled to the input of the first amplifier circuit,
wherein the second transistor has a first terminal coupled to the first power supply terminal, a second terminal coupled to an output of the first amplifier circuit, and a control terminal coupled to the first node, and
wherein the third resistor has a first terminal coupled to the output of the first amplifier circuit and a second terminal coupled to the second terminal.

6. The photoreceptor circuit according to claim 5,
wherein the feedback resistors of the first and second amplifier circuits have a substantially identical resistance, and
wherein the second resistor of the inverting amplifier of the second amplifier circuit has a resistance higher than a resistance of the second resistor of the inverting amplifier of the first amplifier circuit.

7. The photoreceptor circuit according to claim 6,
wherein the first resistor has a resistance higher than the respective feedback resistors of the first and second amplifier circuits.

8. The photoreceptor circuit, further comprising:
an output transistor that is on/off controlled in accordance with an output of the first amplifier circuit.

9. A photocoupler comprising:
an input element that receives an electrical signal and outputs, to the photodiode, an optical signal according to the electrical signal;
a first amplifier circuit where a feedback resistor is coupled between an input and an output of an inverting amplifier;
a second amplifier circuit that has a configuration substantially identical to a configuration of the first amplifier circuit and supplies a bias current to the first amplifier circuit;
a photodiode having an anode coupled to an input of the first amplifier circuit and a cathode coupled to an input of the second amplifier circuit;
a first resistor coupled between an output of the second amplifier circuit and the input of the first amplifier circuit; and
an output transistor outputting an output signal to an output terminal in accordance with an output of the first amplifier circuit.

10. A photoreceptor circuit comprising:
an amplifier circuit where a feedback resistor is coupled between an input and an output of an inverting amplifier, the amplifier circuit converting a current input into a voltage output;
a bias setting circuit having a configuration similar to a configuration of the amplifier circuit;
a photodiode having an anode electrode coupled to an input terminal of the amplifier circuit and a cathode electrode coupled to an input terminal of the bias setting circuit;
a capacitor coupling an output terminal of the bias setting circuit and the input terminal of the amplifier circuit; and
a resistor coupled in parallel to both terminals of the capacitor.

11. The photoreceptor circuit according to claim 10,
wherein, when the photodiode receives an optical signal, a potential difference occurs between the input and output terminals of the bias setting circuit in accordance with the optical signal, and then a current passing through the capacitor and the resistor in accordance with a temporal change in the potential difference is superimposed on an photocurrent generated from the optical signal by the photodiode and then inputted to the input terminal of the amplifier circuit.

12. The photoreceptor circuit according to claim 10,
wherein respective input and output transistors of the amplifier circuit and the bias setting circuit each comprise a bipolar transistor, and
wherein a bias current supplied to the amplifier circuit by the bias setting circuit is smaller than a base current of the input transistor of the amplifier circuit.
